(19) United States
(12) Patent Application Publication
(10) Pub. No.: US 2023/0274920 A1
(43) Pub. Date: Aug. 31, 2023

(54) SYSTEM AND METHOD FOR MAKING THICK-MULTILAYER DIELECTRIC FILMS

(71) Applicant: INTEVAC, INC., Santa Clara, CA (US)

(72) Inventors: Terry Bluck, Santa Clara, CA (US); Samuel D. Harkness, IV, Albany, CA (US); Tom Nolan, Santa Clara, CA (US)

(21) Appl. No.: 18/110,269

(22) Filed: Feb. 15, 2023

Related U.S. Application Data
(60) Provisional application No. 63/310,548, filed on Feb. 15, 2022.

(51) Int. Cl. H01J 37/34; H01J 37/32

(52) U.S. Cl. CPC H01J 37/3405; H01J 37/3452; H01J 37/32761; H01J 37/3244; H01J 37/32623

(57) ABSTRACT

A linear processing system having an entry loadlock, a first multi-pass processing chamber coupled to the entry loadlock, the first multi-pass processing chamber having a sputtering magnetron arrangement and configured to house a single substrate carrier for performing a multi-pass processing; a single-pass chamber coupled to the first multi-pass processing chamber and having a plurality of magnetron arrangements arranged along a carrier travel direction, the single-pass chamber configured to house multiple carriers arranged serially in a row and configured for a single-pass processing; a second multi-pass processing chamber coupled to the single-pass processing chamber, the second multi-pass processing chamber having a sputtering magnetron arrangement and configured to house a single substrate carrier for performing a multi-pass processing; and an exit loadlock chamber coupled to the second multi-pass processing chamber.

### RELATED APPLICATIONS

This application claims priority benefit from U.S. Provisional Patent Application No. 63/310,548, filed on Feb. 15, 2022, the disclosure of which is incorporated herein by reference in its entirety.

### BACKGROUND

### 1. Field

This disclosure relates to systems for forming thin layers on substrates using vacuum chambers.

### 2. Related Art

Traditional systems for forming thin films on substrates employed the conventional batch processing architecture, wherein multiple substrates are positioned within the vacuum chamber and the same thin film is deposited on all of the substrates simultaneously. However, as the requirements of the deposited films characteristics became more and more stringent, artisans began to look at architectures wherein a single substrate is processed in one vacuum chamber, thus providing enhanced control over the formation of the film. Of course, processing one substrate at a time leads to slowing of the manufacturing line and thus increase in costs.

Applicant has previously disclosed various systems for processing substrates, including systems for forming thin layers on substrates individually, using various unique architectures. One example is the system disclosed in U.S. Pat. No. 6,919,001, the disclosure of which is incorporated herein by reference in its entirety. The disclosed system employs “double-decker” in-line architecture wherein at each station a single substrate is processed in a static mode—i.e., the substrate is stationary as the film is deposited. At the end of each processing period, all of the substrates are moved to the next station, such that the substrates are moved on individual carriers “back-to-back” until each substrate is processed by each of the vacuum chambers in the system. This system garnered years of commercial success and is marketed under the commercial name 200Lean®.

Another architecture disclosed by the Applicant is described in U.S. Pat. No. 9,914,994, the disclosure of which is incorporated herein by reference in its entirety. The disclosed architecture enables combining static and pass-by processing concurrently. The static processing is similar to the processing disclosed in the '001 patent cited above, while in pass-by processing the substrate is moved in front a source during the deposition process, such that the thin film is formed on the substrate from the leading edge to the trailing edge.

As technology advances and the requirements of the various deposited layers change, at times the desired process parameters do not lend themselves well to usage of existing architectures. For example, when processing substrates in a back-to-back manner, it is desirable that at all of the stations the processing time, i.e., takt time, is the same, so that each chamber starts and ends the process at the same time, enabling the substrates to move to the next station and start processing again. However, at times multiple layers of different material, different thickness, etc., are required to be deposited on the substrates. For example, to make durable scratch resistant optical films, multiple thin layers, e.g., less than 250 nm, and at least one thick layer, e.g., thicker than 500 nm is required. The multiple thin layers are used to modify optical properties, such as reducing reflectance, or modify mechanical properties such as Young's modulus. Such requirement may complicate the takt time or may require increasing the number of processing chambers, which would increase the manufacturing costs and results in a great deal of WIP inside the system.

Traditional drum coaters are inexpensive and can deposit multiple layers; however, they have several limitations. Since they swing an arc past the deposition sources, the substrate size is limited due to uniformity concerns. Also, they cannot deposit multiple layers with differing properties simultaneously. For example, a SiON film with an index of 1.65 cannot be deposited in a drum coater while also depositing a SiON film with an index of 1.90. In addition to poorly controlled intermixing of reactive gases, there is too much fluid communication between sources. Furthermore, since a drum coater vents the process chambers between batches, it can create particles and process variations due to water vapor uptake.

### SUMMARY

The following summary of the invention is included in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Disclosed embodiments provide system architecture enabling deposition of multiple thin layers of different characteristics and different thicknesses, while reducing WIP tied up in the system during fabrication. The disclosed embodiments provide a linear processing system, wherein substrates enter from one side, traverse the system for forming the various layers, and exit from the opposite side. The system includes multiple vacuum chambers, some of which are configured for a “one-way” pass-by processing, while others are configured for “forward-reverse” pass-by processing.

In a related aspect, disclosed embodiments provide a vacuum processing chamber segmented or sectioned into operational units. Some of operational units are configured for a “one-way” pass-by processing, while others are configured for “forward-reverse” pass-by processing. Each section generally comprises independently accessed transport control necessary to enable different processing modes and move carriers between sections for each subsequent processing step. Single pass sections generally require independent speed control even within one section so as to optimally position the carriers together “head-to-toe” as they sequentially arrive from the previous processing section.

The transport control system simultaneously employs at least three different motion speeds: at least one transport speed to transport carriers through loadlocks and into the in-line system/chamber as well as between in-line processing sections, at least one first process speed tailored for the “one-way” pass-by processing, and at least one second process speed, configured for “forward-reverse” pass-by processing. Generally, second process speeds required for forward-reverse pass-by processing sections are significantly faster than first process speeds required for one-pass sections.

One disclosed embodiment of a linear processing system comprises: an entry loadlock chamber; a first multi-pass processing chamber or section coupled to the entry loadlock section, the first multi-pass processing chamber or section having a sputtering magnetron arrangement and configured to house a single substrate carrier for performing a multi-pass processing; a single-pass chamber or section coupled to the first multi-pass processing chamber or section and having one or more magnetron arrangements arranged along a carrier travel direction, the single-pass chamber or section configured to house multiple carriers arranged serially in a row and configured for a single-pass processing; a second multi-pass processing chamber or section coupled to the single-pass processing chamber, the second multi-pass processing chamber or section having a sputtering magnetron arrangement and configured to house a single substrate carrier for performing a multi-pass processing; and an exit loadlock chamber coupled to the second multi-pass processing chamber or section.

Also, a sputtering chamber is disclosed, comprising: a vacuum chamber having an entrance slit and an exit slit enabling transport of a substrate carrier therethrough; at least one magnetron arrangement provided in the vacuum chamber, the magnetron arrangement comprising two magnetrons arranged serially in the travel direction of the substrate carrier; a gas injector positioned to inject reactive gas between the two magnetrons; wherein no gate valve is provided in the entrance slit and the exit slit.

Additionally, a sputtering system is provided, comprising: at least one multi-pass chamber configured to house a single substrate carrier; at least one single-pass chamber configured to house a plurality of substrate carriers and coupled to the multi-pass chamber; a transport mechanism transporting the plurality of substrate carriers within the single-pass chamber in unison at a first transport speed and transporting the single carrier within the multi-pass chamber in a forward and reverse motions at a second speed faster than the first speed.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements and are not drawn to scale.

FIG. 1 is a general schematic of a system according to disclosed embodiment.

FIG. 2 is a general schematic cross-section along line A-A of FIG. 1, while FIG. 2A is a modified embodiment utilizing optional buffer chambers or sections and FIG. 2B illustrates an embodiment made of modular sections.

FIGS. 3A and 3B illustrate embodiments having a single multi-pass chamber or section and multiple multi-pass chambers or sections, respectively.

### DETAILED DESCRIPTION

Embodiments of the inventive sputtering system will now be described with reference to the drawings. Different embodiments may be used for processing different substrates or to achieve different benefits, such as throughput, film uniformity, target utilization, etc. Depending on the outcome sought to be achieved, different features disclosed herein may be utilized partially or to their fullest, alone or in combination with other features, balancing advantages with requirements and constraints. Therefore, certain features and benefits will be highlighted with reference to different embodiments, but are not limited to the disclosed embodiments, and the features may be incorporated in other embodiments or with other combinations.

Applicant has previously disclosed an architecture of a linear system, wherein the system's chambers and sections are arranged linearly, such that substrate carriers move from one chamber or section directly to the next. See, U.S. Pat. No. 9,502,276, the disclosure of which is incorporated herein by reference in its entirety. The '276 patent disclosure provides details about various manners of arranging the chambers linearly, the use of carriers to transport substrates, and the loading and unloading of substrates from the system. Therefore, such discussion will not be repeated herein, and the reader is directed to the '276's disclosure for such details.

The following disclosure includes embodiments of a unique system architecture that combines two types of processing motions in a single inline system. Disclosed features include improved reactant gas control between processing chambers or sections, ability to form layers of different types and different thicknesses, reduced system WIP, small system footprint, and more. In disclosed examples the magnetrons are used in pairs, wherein for thick individual layers multiple pairs are used while for thin layers single pairs are used. To deposited thin layers the substrate passes multiple times back and forth past the single source pair. Each pass can deposit a different layer, e.g., pass one could deposit a 1.6 refractive index film and pass two could deposit a 1.9 index film, so on and so forth. Conversely, each pass can deposit the same type of film so that the thickness is increased with each pass. To deposit thick layers, multiple pairs of sources could be used. The substrate moves past these sources in forward motion at a slower speed, with the substrates or carriers arranged head to toe. In disclosed embodiments in the “inline forward”, one pass deposition chamber(s) or section(s) the carriers are arranged head to toe, while in each of the “forward-reverse” chambers there is only one carrier. This arrangement greatly reduces the WIP without limiting the system throughput.

This architecture yields the best benefits of a batch system: multiple passes past a source or sources, and the best benefits of an inline system with load locks: good uniformity and high productivity. It is achieved by having different processing types performed in a single in-line processing flow. The disclosed in-line processing flow can be fabricated by a single unitary chamber, or it can be fabricated by interconnecting sections. Therefore, in this sense the entire line can be conceptually thought of as a system made up of multiple chambers, or a single processing chamber made up of different section, wherein each section may be fabricated separately and then connected to other sections to form the complete chamber. Hence, in this description the references to chambers and sections may be interchangeable.

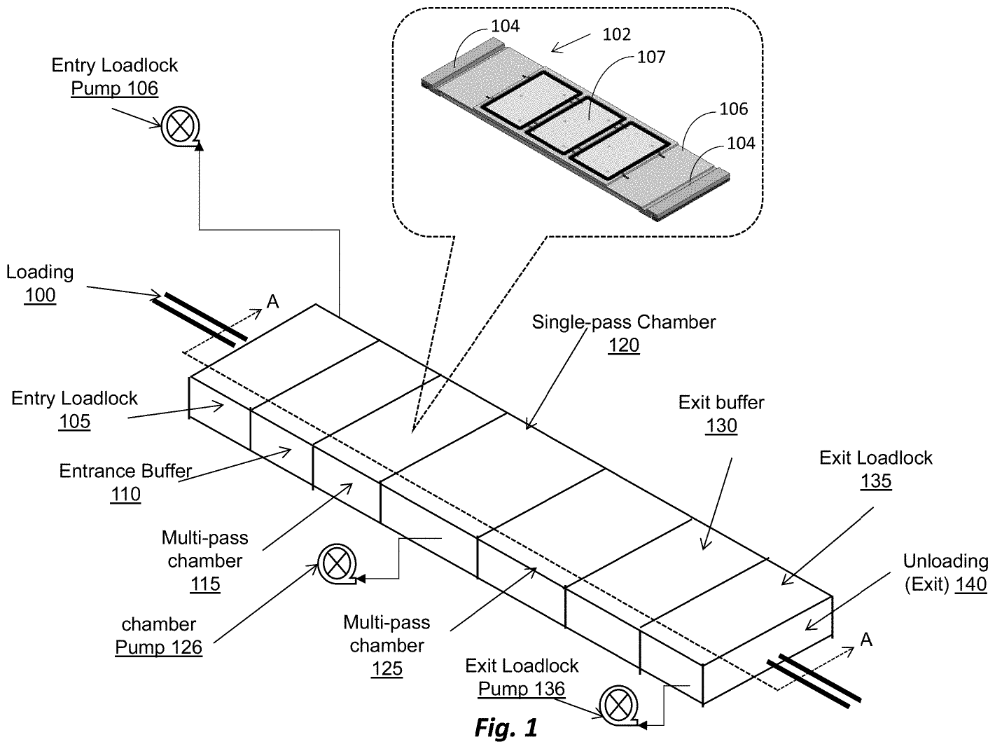

FIG. 1 is a general schematic of a system according to a disclosed embodiment, wherein details relating to the loading and unloading of substrates from the system are omitted for clarity. Also, while the loading 100 and unloading 140 are illustrated at opposite sides of the system, as explained in the '276 patent, various mechanisms can be employed to transfer substrate carriers from the unloading side to the loading side, so that both loading and unloading can be done from the same side of the system, while the carriers still traverse the entire system in a linear fashion. While loading and unloading is performed in atmospheric environment, the carriers traverse the entire system in vacuum environment, by first entering the entry loadlock chamber 105, and exiting the system via exit loadlock chamber 135. As shown, the system may optionally include entrance buffer chamber 110 and exit buffer chamber 130 to assist in matching takt time in the system and enable multi-pass in forward and reverse. The “heart” of the system comprises a connected in-line vacuum chamber made up of multi-pass processing sections and single-pass processing sections. By multi-pass it is meant that carriers processed in such a section are moved forward and reverse multiple times to form multiple layers serially, i.e., in each pass one layer is formed. By single-pass it is meant that the carriers processed in such a section traverse the processing section only once in a forward direction motion. In the embodiment shown in FIG. 1, the carriers are first processed in a multi-pass section 115, then in a single-pass section 120, then in the multi-pass section 125, and then exit the system passing exit buffer 130 and exit loadlock 135. More or less multi-pass sections and more than one single-pass sections may be included in the in-line processing chamber of the system.

The substrates are transported throughout the system on carriers, such as carrier 102 shown in the callout of FIG. 1. Carrier 102 may be configured for mounting one or multiple substrates thereupon—where FIG. 1 illustrates three substrates 107 as but one example. In this example, the carrier has a main body 106 upon which the substrates 107 are placed, flanked by two rails 104, which ride on magnetic wheels positioned inside the vacuum chamber and are therefore obscured from view in FIG. 1.

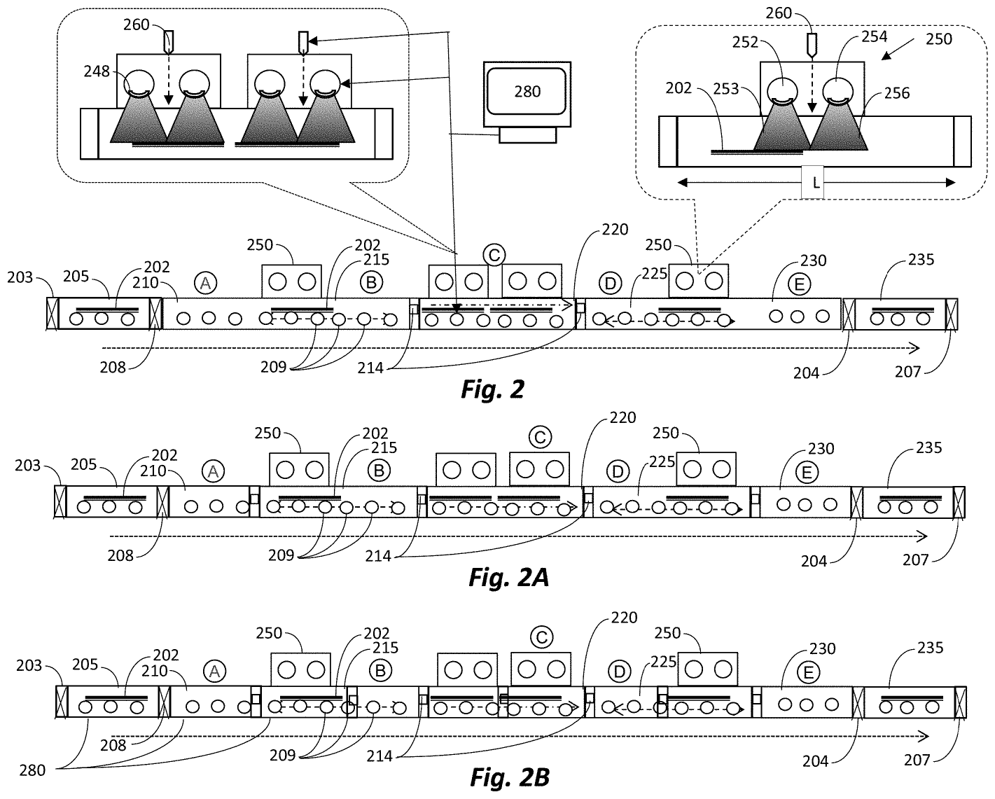

FIG. 2 schematically illustrates a cross section along lines A-A in FIG. 1, with the dotted arrow showing the general direction of the carriers' progress during processing. The entry loadloack 205 is isolated from the atmospheric environment via gate valve 203 and from buffer area/chamber 210 via gate valve 208. When a carrier 202 enters the loadlock 205, gate valve 203 is open and gate valve 208 is closed. Once the carrier 202 is within the loadlock, gate valve 203 closes and the loadlock is pumped to vacuum condition. Then gate valve 208 is opened and carrier 202 can be moved to the buffer area/chamber 210. The opposite process occurs at the other end to release carrier 202 via loadlock 235.

Notably, in FIG. 2 buffer areas 210 and 230 are illustrated as being part of their respective multi-pass chambers 215 and 225. Conversely, in FIG. 2A the optional buffer chambers 210 and 230 are employed, enabling to construct the multi-pass chambers smaller. Either embodiment may be used for the processing described below with equal efficiency. Thus, in the context of this disclosure, references to buffer chamber or buffer area may be interchangeable.

The fabrication of the multiple layers on the substrates proceeds as follows. Each of the multi-pass chambers 215 and 225 includes a magnetron pair 250 that sputters the material to be deposited onto the substrates. In this embodiment, each magnetron of a pair of magnetrons 250 sputters the same material as the other magnetron of the same pair, but the pair of chamber 215 may sputter material different from the pair of chamber 225. In each of multi-pass chambers 215 and 225 the carriers make several passes under the magnetron pair 250 by moving forward and backward multiple times, i.e., minimum of two forward and one backward motions. Each motion, whether forward or reverse is considered as one pass, and for each pass the controller 280 may vary the parameters of the sputtering process, e.g., magnetron power, reactive gas flow, substrate bias, transport speed, etc., such that the resulting film may have different characteristics, e.g., different thickness, different refractive index, etc.

Each of the multi-pass chambers 215 and 225 are said to be configured for a multi-pass deposition process in that the length of carrier travel within the chamber—marked L in the dashed callout of FIG. 2—is sufficiently long to enable the carrier to place a substrate completely ahead and outside of the cone of deposition 253 formed by the leading magnetron 252, and completely behind and outside of the cone of deposition 256 of the trailing magnetron 254, as schematically shown in the dashed callout in FIG. 2. In this manner, starting from either side of the chamber, the carrier can be in a positioned within the chamber but with the substrates outside of the deposition zone defined by the two abutting deposition cones, travel towards the opposite side of the chamber such that the substrate traverses the entire deposition zone, and then completely exit the deposition zone but remain within the chamber. In the context of this disclosure, the term “cone of deposition” is used to conceptually refer to the active deposition region of the magnetron, and not necessarily refers to the shape of that active deposition region.

Alternatively, the chamber can be configured for multi-pass processing by having its length of travel extended on one side of the deposition zone to enable to place the substrate outside of the deposition zone, while on the other side having a buffer chamber, e.g., buffer chamber 210 or 230, serving to place the substrate outside of the zone of deposition, as schematically shown in FIG. 2A.

The single pass chamber 220 includes multiple pairs of magnetrons 250—as an example FIG. 2 shows two pairs. As shown by the dash-dot arrow, the carriers traverse chamber 220 in only one pass in one direction, generally referred to as the processing direction or forward direction. Also, while the multi-pass chambers are configured to house a single carrier moving independently in each chamber, the multi-pass chamber 220 is configured to house multiple carriers arranged one behind the other and moving together like train cars. These different motions can be controlled by the controller 280 by, e.g., energizing the magnetic wheels 209. Additionally, as illustrated in the dotted callout, the single-pass chamber is constructed such that there is insufficient space within the chamber to house a carrier outside of the cone of deposition. Consequently, a carrier entering the single-pass chamber must move continuously at a set constant speed until it leaves the single-pass chamber—otherwise the uniformity of the formed layer would be unacceptable.

Thus, a linear processing system is disclosed, comprising: an entry loadlock; a first multi-pass processing chamber coupled to the entry loadlock chamber, the first multi-pass processing chamber having a sputtering magnetron arrangement and configured to house a single substrate carrier for performing a multi-pass processing; a single-pass chamber coupled to the first multi-pass processing chamber and having a plurality of magnetron arrangements arranged along a carrier travel direction, the single-pass chamber configured to house multiple carriers arranged serially in a row and configured for a single-pass processing; a second multi-pass processing chamber coupled to the single-pass processing chamber, the second multi-pass processing chamber having a sputtering magnetron arrangement and configured to house a single substrate carrier for performing a multi-pass processing; and an exit loadlock chamber coupled to the second multi-pass processing chamber.

As shown in FIG. 2, entry loadlock chamber 205 is isolated using gate valves 203 and 208. Similarly, exit loadlock chamber 235 is isolated using gate valves 204 and 207. However, a feature of this embodiment is that no gate valves are provided between any of the processing chambers or sections. Rather, open slits 214 is provided between hardware components of the in-line processing system (i.e., between each two processing or buffer chambers or sections), enabling free flow therethrough. Thus, the slits 214 enable free motion of the carriers among the processing and buffer chambers or sections, without the need to await opening and closing of a gate valve. Buffer areas also comprise open slits, as shown in FIG. 2A. This advantageous feature is enabled, at least in part, by the unique arrangement of the magnetron pairs 250.

FIG. 2B illustrates another embodiment wherein a single vacuum chamber is made up of multiple modular sections, wherein each section can be made into a buffer section or a processing section. As illustrated in FIG. 2B, the entire system is made up of multiple sections 280, wherein all may have the same size in terms of width, height and length. All of the sections 280 are connected together to form one vacuum enclosure that can be referred to as the processing system or the processing chamber. The first section 280 is made into a loadlock chamber by having gate valve 203 attached to its entrance and gate valve 208 attached at its exit side. The same is doe to form the exit loadlock 235. The remainder sections are connected to each other without gate valves, thus forming one vacuum chamber having a common vacuum environment among its sections 280. Each of the loadlock chambers require its own independently operable vacuum pump (See FIG. 1), but the main processing chamber may utilize one or more vacuum pump to evacuate all of its sections, since there's no isolation in between the sections.

In the embodiment illustrated in FIG. 2B, a modular section can accommodate a paired magnetron. For example, one section 280 may be outfitted with a paired magnetron 250 to form multi-pass chamber 215. In order to enable the multiple pass facility, two modular sections 280 without magnetrons are attached to section 215, thus forming two buffer section, one upstream and one downstream of multi-pass section 215. Conversely, if a section 280 is to function as a single pass section, then no buffer stations are needed. Thus, for example, two modular section 280, each fitted with a pair of magnetrons can be connected together and form a larger single-pass section.

Thus, a linear processing chamber is disclosed, comprising: a plurality of sections attached together in a linear fashion, wherein the plurality of sections include at least: a first gate valve is attached at an entrance of a first section of the chamber, a second gate valve is attached at an exit of the first section; a third gate valve is attached to an entrance of a last section and a fourth gate valve is attached at an exit of the last section; a second section attached to the first section forms a first buffer station; a third section attached to the second section is fitted with a first pair of magnetrons and forms a multi-pass section; a fourth section attached to the third section forms a second buffer station; a fifth section is fitted with a pair of magnetrons and forms a single-pass section.

As shown in the dashed and the dotted callouts, each magnetron arrangement 250 comprises a pair of magnetrons, e.g., 252 and 254, arranged serially in the direction of processing, such that a traveling carrier moves past a first and a second magnetron. Each magnetron includes a target 248 made of the material to be sputtered onto the substrate to form the desired layer. The sputtering of the target is done by maintaining plasma about the magnetron. Reactive gasses, such as oxygen, nitrogen, etc. are injected via injector 260, strategically positioned between two magnetrons, to thereby inject the reactive gases in between the pair of magnetrons. This unique arrangement results in the following benefits. As the gas is injected between two paired magnetrons, the gas is “pumped” by the depositing film, i.e., by the flow of sputtered material in the cone of deposition. This pumping action consumes the reactants within the gas, thereby efficiently utilizing the supplied gas and reducing reactants outflow through the slits, that might otherwise reach other layers. Conversely, reactant that might arrive from other magnetron pairs is similarly “pumped” at the outside edges of the deposition cones. Such process “pumping” significantly reduces the effect of deposition in one section upon deposition in another section. Reactive gas interchange between the active processing regions of connected sections is further reduced by active vacuum pumping in the buffer regions surrounding the active regions of each section such that the change in reactive gas flow and corresponding film properties of a film deposited in one section owing to changes in the reactive gas flows of a connected section can generally be reduced to an inconsequential level. Therefore, with this arrangement, no valve gates are needed between processing chambers and fluids are allowed to freely flow in between processing chambers.

Thus, a sputtering chamber is disclosed, comprising: a vacuum chamber having an entrance slit and an exit slit enabling transport of a substrate carrier therethrough; at least one magnetron arrangement provided in the vacuum chamber, the magnetron arrangement comprising two magnetrons arranged serially in travel direction of the substrate carrier; a gas injector positioned to inject reactive gas between the two magnetrons; wherein no gate valve is provided in the entrance slit and the exit slit.

Also, an active sputtering module is disclosed, comprising: an entrance slit and an exit slit enabling transport of a substrate carrier therethrough, while partially restricting conductance of gases into and out of buffer regions flanking the module; at least one magnetron arrangement provided between the transport slits, the magnetron arrangement comprising two magnetrons arranged serially in travel direction of the substrate carrier; a gas injector positioned to inject reactive gas between the two magnetrons; wherein no gate valve is provided in the entrance slit and the exit slit.

Another feature of the disclosed embodiment is that the system employs at least three different motion speeds: a transport speed, a first process speed and a second process speed, wherein the first process speed is tailored for the “one-way” single-pass processing, while the second process speed is configured for “forward-reverse” multi-pass processing. Generally, the second process speed is faster than the first process speed. That is, the second speed is configured such that a carrier in the multi-pass chamber traveling at the second process speed can perform at least two forward and one reverse passes during the time that a carrier in the single-pass chamber traveling at the first process speed performs one (forward) pass. A pass is considered as starting from a position wherein the substrate positioned on the carrier is outside of the cone of deposition, the carrier travels through the cone of deposition until the entire substrates passes through the cone of deposition and completely exits the cone of deposition. For the purpose of defining a pass, the cone of deposition refers to the deposition of sputtered material from two paired magnetrons. Also, in the disclosed embodiments a transport mechanism, e.g., magnetic wheels energized by a controller, is configured to move a carrier in the multi-pass chamber independently, while moving carriers in the single-pass chamber in unison. Further transport mechanisms may be employed to transport and position carriers between sections and into and out of the system. Stated another way, the second transport speed is applied to each carrier traveling inside a multi-pass chamber independently, while the first speed applies uniformly to all carriers positioned within the single-pass chamber. Notably, within the multi-pass chamber, each pass may employ a different process recipe, which may include a different process speed, in addition to different gas flow rates and different sputter power. Regardless, the second transport speed is configured such that the time to complete one pass in the multi-pass chamber is less than the time to complete one pass in the single-pass chamber, i.e., while the second speed is variable between passes, it is always faster than the first speed.

Thus, a sputtering system is provided, comprising: at least one multi-pass chamber configured to house a single substrate carrier; at least one single-pass chamber configured to house a plurality of substrate carriers and coupled to the multi-pass chamber; a transport mechanism transporting the plurality of substrate carrier within the single-pass chamber in unison at a first transport speed and transporting the single carrier within the multi-pass chamber in a forward and reverse motions at a second speed faster than the first speed.

In other aspects, a linear sputtering system is provided, comprising an entry loadloack chamber and an exit loadlock chamber; an in-line processing chamber allowing carriers to pass from said entry loadlock chamber to said exit loadlock chamber during processing, said in-line processing chamber having a plurality of sections comprising at least one single-pass processing section positioned between the entry loadlock chamber and the exit loadlock chamber, and at least one multi-pass processing section positioned between the entry loadlock chamber and the single-pass processing section or between the single-pass processing section and the exit loadlock chamber; a plurality of substrate carriers; a transport system transporting the substrate carriers through the entry loadlock chamber, the at least one single-pass process sections, the at least one multi-pass process section and the exit loadlock chamber at multiple speeds independently controlled in different sections and chambers; wherein the at least one multi-pass processing section comprises a sputtering magnetron arrangement and is configured to include front and rear buffer regions to house a single substrate carrier for performing a multi-pass processing, and the at least one single-pass section comprises one or more magnetron arrangements arranged along a carrier travel direction, the single-pass section is configured to include buffer areas to house carriers entering and exiting the single pass processing section as well as multiple carriers arranged serially in a row and configured for a single-pass of continuous processing.

In FIGS. 2 and 2A, different zones within the system are identified as A, B, C, D, and E. The transport mechanism transports the substrate carriers among these zones in the following manner. A carrier inside the entry loadlock 205 is transported to zone A at a transport speed, which is a higher speed than the first process speed and the second process speed. During a forward processing motion from A to B and during a reverse processing motion from B to A, the carrier is moved at a second processing speed, which may be different for each pass depending on the process recipe for the particular pass. When processing in the first multi-pass chamber is completed and a gap exists between the leading edge of the carrier in zone B and the trailing edge of the last carrier in zone C, the carrier may be transported from zone B to zone C at a transport speed to be placed behind the last carrier in zone C. Within zone C all the carriers are moved in unison at a first transport speed, which is the slowest speed employed by the transport mechanism. When a trailing edge of a carrier within zone C exits the last cone of deposition of the single-pass active deposition chamber 220 it enters zone D. The carrier then performs multiple passes in forward and reverse directions at the second process speed, which may be different for each pass, depending on the recipe. Once the multiple passes are completed, the carrier is moved from zone E to the exit loadlock 235 at a transport speed. Thus, in this disclosed embodiment while the first process speed is fixed, the second process speed is variable and recipe dependent.

With the disclosed embodiments the following example multi-layer fabrication process is enabled. In the first multi-pass chamber 215, a plurality of thin layers are formed on the substrate. Each pass forms a single thin layer, e.g., of thickness less than 250 nm. The recipe at each pass can be changed, e.g., by changing the flow rates of the reactive gases, such as oxygen and nitrogen, the refractive index of each layer can be varied. In one example, the recipes are programmed such that the resulting layers comprise an index matched adhesion layer structure that provides both optical properties matched to the substrate and a low stress adhesive structure that provides improved bonding between the substrate and a subsequent single-pass thick layer.

In the single-pass chamber a thick layer can be formed by slow motion of the carrier moving under multiple pairs of magnetrons. When the targets of all of the magnetron pairs in the single-pass chamber are the same, one thick layer, e.g., thicker than 500 nm can be formed. For example, a hard protective layer can be formed over an adhesion layer. Further thin layers can be formed over the hard protective layer in the second multi-pass chamber 225. In one example, the recipes are programmed such that the resulting layers are interlaced layers having high and low refractive indices by having alternating layers of high nitrogen flow and high oxygen flow (where nitrogen leads to higher refractive index). Using this example, a scratch resistant anti-reflective film can be formed on the hard protective layer by multiple passes in the multi-pass section. Other layers may be formed to further control the overall optical and mechanical properties of the coating. The resulting layer has hardness higher than 8 GPa and transmissivity higher than 94%.

The various coatings can be formed using targets made of, for example silicon, aluminum, a mixture of silicon and aluminum, etc., in conjunction with injection of reactive gases such as oxygen and nitrogen. Thus, the formed layers may include SiOx, SiNx, SiOxNy, AlOx, AlNx, AlOxNy, SiAlOx, SiAlNx, SiAlOxNy, etc. It should be understood that for illustration purpose the use of oxygen and nitrogen is disclosed, but any Oxynitride film could be used.

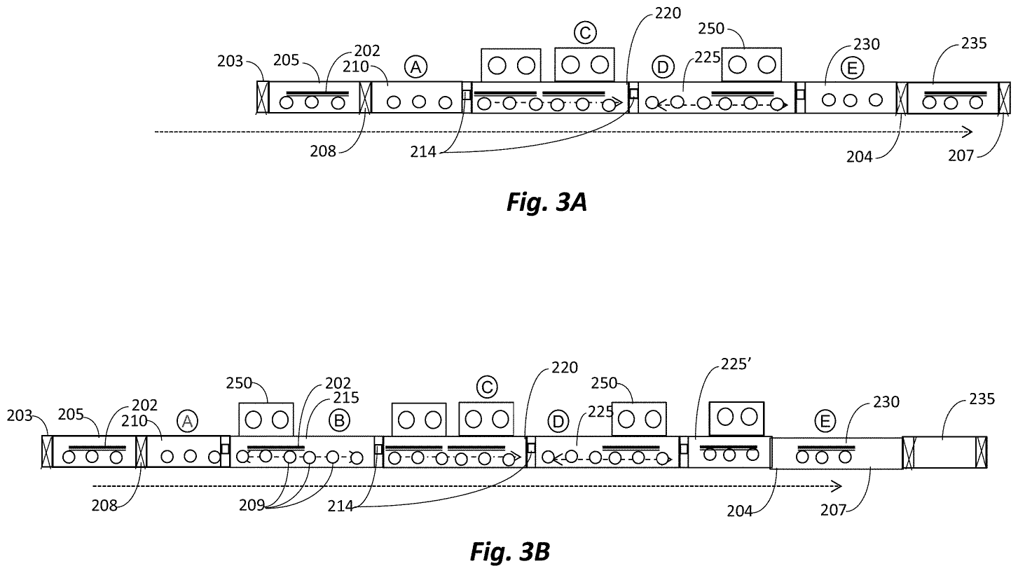

Notably, if the multiple thin layers are needed only under the thick layer, then multi-pass processing chamber 225 may be dispensed with. Conversely, if the multiple thin layers are needed only over the thick layer, then multi-pass process chamber 215 may be dispensed with. Thus, in this sense, the system may have one single-pass process chamber and at least one multi-pass process chamber, as exemplified in FIG. 3A. Conversely, the system may have multiple multi-pass process chambers either upstream or downstream of the single-pass chamber, as exemplified in FIG. 3B. Unusually complicated layer stacks with multiple thick and thin layers interspersed may require multiple sections configured for single-pass processing as well as one or more multi-pass sections.

While the disclosed embodiments are described in specific terms, other embodiments encompassing principles of the invention are also possible. Further, operations may be set forth in a particular order. The order, however, is but one example of the way that operations may be provided. Operations may be rearranged, modified, or eliminated in any particular implementation while still conforming to aspects of the invention.

All directional references (e.g., upper, lower, upward, downward, left, right, leftward, rightward, top, bottom, above, below, etc. are only used for identification purposes to aid the reader's understanding of the embodiments of the present invention, and do not create limitations, particularly as to the position, orientation, or use of the invention unless specifically set forth in the claims. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

In some instances, components are described with reference to “ends” having a particular characteristic and/or being connected to another part. However, those skilled in the art will recognize that the present invention is not limited to components which terminate immediately beyond their points of connection with other parts. Thus, the term “end” should be interpreted broadly, in a manner that includes areas adjacent, rearward, forward of, or otherwise near the terminus of a particular element, link, component, member or the like. It is intended that all matter contained in the above description or shown in the accompanying drawings shall be interpreted as illustrative only and not limiting. Changes in detail or structure may be made without departing from the spirit of the invention as defined in the appended claims.

It must be noted that as used herein and in the appended claims, the singular forms “a”, “an”, and “the” include plural referents unless the context clearly dictates otherwise.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention.

1. A linear sputtering system, comprising:
an entry loadloack chamber and an exit loadlock chamber;
an in-line processing chamber allowing carriers to pass from said entry loadlock chamber to said exit loadlock chamber during continuous processing, the in-line processing chamber comprising:
at least one single-pass processing section positioned between the entry loadlock chamber and exit loadlock chamber;
at least one multi-pass processing section positioned between the entry loadlock chamber and the exit loadlock chamber;
a plurality of substrate carriers;
a transport system transporting the substrate carriers through the entry loadlock chamber, the at least one single-pass process section, the at least one multi-pass process section and the exit loadlock chamber at multiple speeds independently controlled in different sections and chambers;
wherein the at least one multi-pass processing section comprises a sputtering magnetron arrangement and is configured to include front and rear buffer regions to house a single substrate carrier for performing a multi-pass processing, and the at least one single-pass chamber comprises one or more magnetron arrangements arranged along a carrier travel direction, the single-pass chamber configured to include buffer areas to house carriers entering and exiting the single pass processing section as well as multiple carriers arranged serially in a row for a single-pass of continuous processing.

2. The system of claim 1, wherein the sputtering magnetron arrangement comprises a paired magnetron forming abutting sputtering cones and the one or more sputtering magnetron arrangements comprises at least one paired magnetron.

3. The system of claim 2, wherein each of the paired magnetrons comprises a gas injector positioned between the paired magnetrons.

4. The system of claim 1, wherein one multi-pass processing section is positioned between the entry loadlock and the single-pass processing section and a second multi-pass processing section is positioned between the single-pass processing section and the exit loadlock.

5. The system of claim 4, wherein an open slit without a gate valve is provided between each of the multi-pass processing sections and the single-pass processing section.

6. The system of claim 1, wherein the transport system transports the plurality of substrate carriers within the single-pass section in unison at a first transport speed and transports the single carrier within the multi-pass section in a forward and reverse motions at a second speed faster than the first speed.

7. The system of claim 6, wherein the second speed is configured such that the single carrier in the multi-pass section traveling at the second process speed can perform at least two forward and one reverse passes during the time that a carrier in the single-pass section traveling at the first process speed performs one pass.

8. The system of claim 1, further comprising at least one buffer section coupled to the multi-pass chamber.

9. A linear processing system, comprising:
an entry loadlock;
a first multi-pass processing chamber coupled to the entry loadlock, the first multi-pass processing chamber having a sputtering magnetron arrangement and configured to house a single substrate carrier for performing a multi-pass processing;
a single-pass chamber coupled to the first multi-pass processing chamber and having a sputtering magnetron arrangement arranged along a carrier travel direction, the single-pass chamber configured to house multiple carriers arranged serially in a row and configured for a single-pass processing;
a second multi-pass processing chamber coupled to the single-pass processing chamber, the second multi-pass processing chamber having a sputtering magnetron arrangement and configured to house a single substrate carrier for performing a multi-pass processing; and
an exit loadlock chamber coupled to the second multi-pass processing chamber.

10. The system of claim 9, wherein each of the magnetron arrangements comprises a paired magnetron, each paired magnetron arranged serially in direction of processing, such that a traveling carrier moves past a first magnetron and then a second magnetron of the paired magnetrons.

11. The system of claim 9, wherein the sputtering magnetron arrangement of the single-pass chamber comprises a plurality of paired magnetrons, each paired magnetron arranged serially in direction of processing, such that a traveling carrier moves past a first magnetron and then a second magnetron of each of the paired magnetrons.

12. The system of claim 10, wherein the first magnetron and the second magnetron of the paired magnetrons comprise targets made of the same material.

13. The system of claim 11, wherein the first magnetron and the second magnetron of the paired magnetrons comprise targets made of the same material.

14. The system of claim 9, further comprising a transport mechanism moving carriers in the first and second multi-pass chambers independently of each other, while moving carriers in the single-pass chamber in unison.

15. The system of claim 9, wherein the single-pass chamber is configured such that a carrier placed within the single-pass chamber cannot be outside the cone of deposition of magnetrons within the single-pass chamber.

16. The system of claim 15, wherein each of the first and second multi-pass chambers is configured such that a carrier placed within the multi-pass chamber can be positioned outside the cone of deposition of magnetrons within the multi-pass chamber.

17. A sputtering system, comprising:
at least one multi-pass chamber configured to house a single substrate carrier;
at least one single-pass chamber coupled to the multi-pass chamber;
a transport mechanism transporting the plurality of substrate carrier within the single-pass chamber in unison at a first transport speed and transporting the single carrier within the multi-pass chamber in forward and reverse motions at a second speed faster than the first speed.

18. The system of claim 17, wherein the second speed is configured such that the single carrier in the multi-pass chamber traveling at the second process speed can perform at least two forward and one reverse passes during the time that a carrier in the single-pass chamber traveling at the first process speed performs one pass.

19. A sputtering chamber, comprising:
a vacuum chamber having an entrance slit and an exit slit enabling transport of a substrate carrier therethrough;
at least one magnetron arrangement provided in the vacuum chamber, the magnetron arrangement comprising two magnetrons arranged serially in travel direction of the substrate carrier;
a gas injector positioned to inject reactive gas between the two magnetrons;
wherein no gate valve is provided in the entrance slit and the exit slit.

20. The chamber of claim 1, wherein each of the two magnetrons comprise targets made of the same material as targets of the other magnetron.
